(19) United States
(12) Patent Application Publication
(10) Pub. No.: US 2025/0088109 A1
(43) Pub. Date: Mar. 13, 2025

(54) CONTROL METHODS AND CIRCUITS FOR ELECTRONIC DEVICES

(71) Applicant: STMicroelectronics International N.V., Geneva (CH)

(72) Inventors: Simone SCADUTO, Mussomeli (IT); Federico IOB, Udine (IT); Stefano SAGGINI, Udine (IT); Liliana ARCIDIACONO, Tremestrieri Etneo (IT); Carmelo Alberto SANTAGATI, Catania (CT) (IT); Agatino Antonino ALESSANDRO, Rho (MI) (IT); Francesco GIORGIO, Brolo (IT)

(73) Assignee: STMicroelectronics International N.V., Geneva (CH)

(21) Appl. No.: 18/828,103

(22) Filed: Sep. 9, 2024

(30) Foreign Application Priority Data
Sep. 11, 2023 (IT) 102023000018543

(51) Int. Cl. H02M 3/158; H02M 1/00; H03K 7/06; H03K 7/08

(52) U.S. Cl. CPC H02M 3/158; H02M 1/0009; H02M 1/0032; H03K 7/06; H03K 7/08

(57) ABSTRACT

A control circuit provides a drive signal to an electronic switch of an electronic converter. A first driving circuit has a first enable node receiving a first enable signal and a PWM signal generator circuit configured to provide a PWM drive signal in response to the first enable signal. A second driving circuit has a second enable node configured to receive a second enable signal and a PFM signal generator circuit configured to provide a PFM drive signal in response to the second enable signal. Logic circuitry coupled to the first and second driving circuits is configured to assert at least one of the first and second enable signals in response to a mode selection signal.

### PRIORITY CLAIM

This application claims the priority benefit of Italian Application for Patent No. 102023000018543 filed on Sep. 11, 2023, the content of which is hereby incorporated by reference in its entirety to the maximum extent allowable by law.

### TECHNICAL FIELD

The description relates to methods and circuits, such as power management or regulation methods and circuits, for (e.g., DC-DC) electronics converter circuits.

One or more embodiments may be used in a variety of application scenarios, such as the automotive field.

### BACKGROUND

Power-supply circuits, such as AC/DC or DC/DC switched mode power supplies, are well known in the art. There exist many types of electronic converters, which are mainly divided into isolated and non-isolated converters. For instance, non-isolated electronic converters are the converters of the “buck”, “boost”, “buck-boost”, “Cuk”, “SEPIC”, and “ZETA” type. Isolated converters are, for instance, converters of the “flyback”, “forward”, “half-bridge”, and “full-bridge” type. Such types of converters are well known to the person skilled in the art, as evidenced, e.g., by the application note AN513/0393 “Topologies for Switched Mode Power Supplies”, L. Wuidart, 1999, STMicroelectronics (incorporated herein by reference).

FIG. 1 is a schematic illustration of a DC/DC electronic converter 20. In particular, a generic electronic converter 20 comprises two input terminals 200a and 200b for receiving a DC voltage V_{IN} and two output terminals 202a and 202b for supplying a DC voltage Vₒᵤₜ. For example, the input voltage V_{IN} may be supplied by a DC voltage source 10, such as a battery, or may be obtained from an AC voltage by means of a rectifier circuit, such as a bridge rectifier (and possibly a filtering circuit). Instead, the output voltage Vₒᵤₜ may be used to supply (e.g., an electric current to) an electrical load 30.

As is well-known, an electronic converter comprises one or more reactive components, such as inductances and/or capacitances, and one or more electronic switches configured to control: the current flow from the input terminals 200a and 200b to the one or more reactive components, and/or the current flow from the one or more reactive components to the output terminals 202a and 202b.

A current intensity in the electrical load 30 can vary over a wide range of values based on different operating regimes of the electronic converter.

As appreciable to those of skill in the art, an electronic (e.g., DC-DC) converter circuit can be operated at least in two operating regimes: a continuous current mode (CCM) regime which could be applied to any load value but whose efficiency is greatly reduced at “light” load (e.g., close to zero) values due to switching losses; and a discontinuous current mode (DCM) regime suited for light load values at the expense of regulation and electromagnetic interference emission (EMI).

Switching between the two operating regimes (CCM to DCM and vice-versa) may be complex and lead to discontinuity on the regulation voltage, burst behavior and offset. Moreover, reducing internal power consumption may be challenging, for instance due to the presence of enable circuitry to drive on and off.

A conventional system for controlling operation of a DC-DC converter is known as peak current mode (PCM).

In a DC-DC converter device equipped with a PCM control loop the transition from/to CCM to/from DCM occurs by means of an internal generated signal referred to as a skip (SKIP) signal.

In another conventional system, such as the pulsed-frequency modulation (PFM) control loop, the internal generated transition control signal is known as pulse skip regulation.

The (pulse regulation) SKIP signal is generated by comparing the output voltage Vₒᵤₜ and a reference voltage used for the PCM regulation. For instance, when the output voltage Vₒᵤₜ is greater than the reference voltage, the internal generated SKIP signal is asserted with a first logic value (e.g., “high” or “1”).

In response to the assertion, the switching activity of the DC-DC converter is interrupted and the output node Vₒᵤₜ goes into a high impedance condition.

Conversely, when the output voltage Vₒᵤₜ is lower than the reference voltage, the internal generated SKIP signal is de-asserted to have a second logic value (e.g., “low” or “0”).

In response to the de-assertion, the switching activity (re-) starts to pump the output load.

Such conventional arrangements can show one or more of the following drawbacks: large ripple on output voltage Vₒᵤₜ, output voltage offset, complexity of burst regulation, small bandwidth PCM loop, in particular in low power consumption, low quality response for a transient current load causing undervoltage on Vₒᵤₜ, and electromagnetic interference.

There is a need in art to contribute to overcoming the aforementioned drawbacks.

### SUMMARY

One or more embodiments may relate to a control circuit.

One or more embodiments may relate to a corresponding electronic device, such as a buck converter, for instance.

One or more embodiments facilitate providing a way to control smoothly operation mode transitions in electronic converter devices.

One or more embodiments exploit a protocol to manage low/high power transitions in a single DC-DC converter.

For instance, a transition from CCM to DCM operating modes of the electronic converter can be performed while consuming very low quiescent current, in particular with light loads.

One or more embodiments facilitate to switch among control loops in various operating regimes very quickly, in a manner exempt from discontinuity in the output regulated voltage provided.

One or more embodiments provide a way of handling the internal enabling circuitry in order to reduce quiescent current consumption during an idle phase.

One or more embodiments involve a relatively simple analog circuitry, providing a simplified design for a controller of a DC-DC converter as a result.

### BRIEF DESCRIPTION OF THE DRAWINGS

One or more embodiments will now be described, by way of non-limiting example only, with reference to the annexed Figures, wherein:

FIG. 1 is a diagram exemplary of an electronic device;

FIG. 2 is a diagram exemplary of an electronic device as per the present disclosure;

FIG. 3 is a diagram exemplary of a portion of the electronic device exemplified in FIG. 2;

FIG. 4 is a diagram exemplary of a further portion of the electronic device exemplified in FIG. 2;

FIG. 5 is a diagram of a control method as per the present disclosure;

FIG. 6 is a diagram of an electronic device as per the present disclosure;

FIGS. 7 and 7A are diagrams showing the evolution over time of signals in one or more embodiments;

FIG. 8 is a diagram of a portion of a control circuit as per the present disclosure;

FIGS. 9 to 14 are diagrams showing the evolution over time of signals in one or more embodiments.

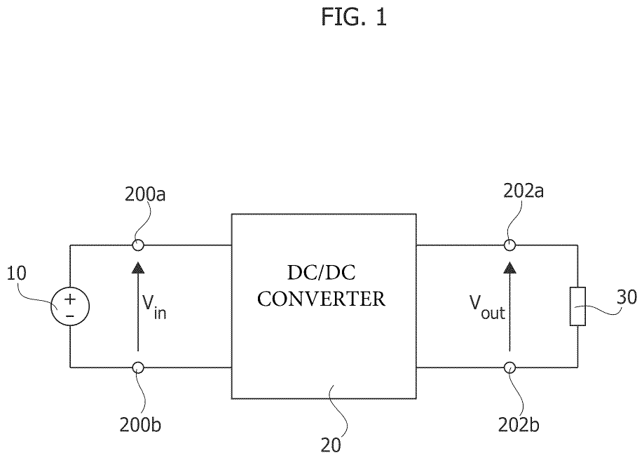

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The references used herein are provided merely for convenience and hence do not define the extent of protection or the scope of the embodiments.

For the sake of simplicity, in the following detailed description a same reference symbol may be used to designate both a node/line in a circuit and a signal which may occur at that node or line.

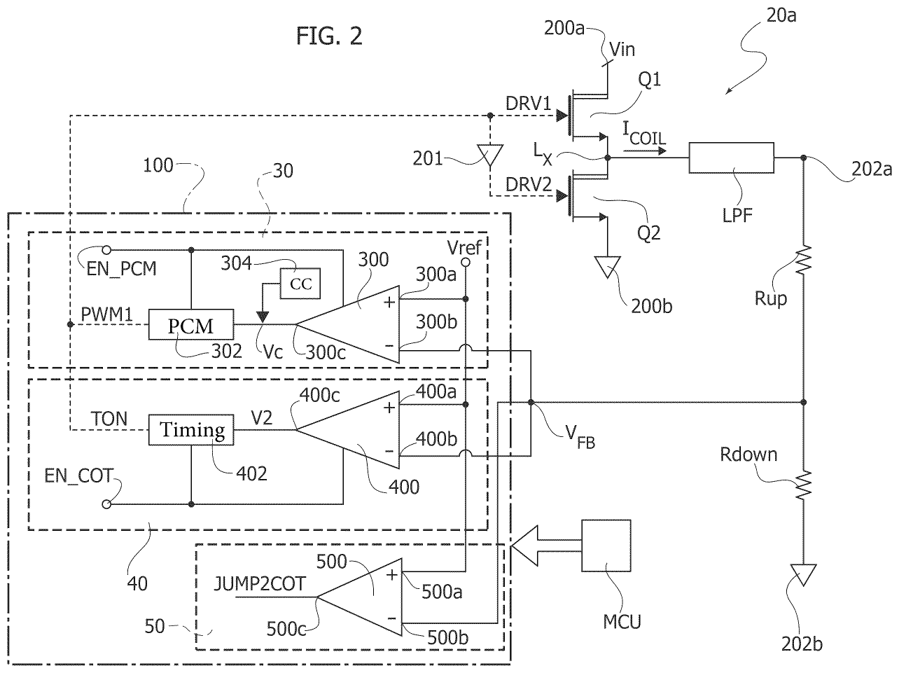

FIG. 2 shows a diagram of an embodiment of a buck converter 20a with an improved control circuit 100. Specifically, the buck converter 20a comprises two input terminals 200a and 200b for receiving a DC input voltage V_{IN} and two output terminals 202a and 202b for supplying an output voltage Vₒᵤₜ, where the output voltage Vₒᵤₜ is equal to or lower than the input voltage V_{IN}.

In the considered example, the buck converter 20a comprises two electronic switches Q1 and Q2 (with the current path thereof) coupled (e.g., directly) in series between the input terminals 200a and 200b, wherein the intermediate node between the electronic switches Q1 and Q2 represents a switching node Lx.

Specifically, the electronic switch Q1 is a high-side switch coupled (e.g., directly) between the (positive) terminal 200a and the switching node Lx, and the electronic switch Q2 is a low-side switch coupled (e.g., directly) between the switching node Lx and the (negative) terminal 200b, which often represents a ground GND. The (high-side) switch Q1 and the (low-side) switch Q2 hence represent a half-bridge configured to connect the switching node Lx to the terminal 200a (voltage V_{IN}) or the terminal 200b (ground GND).

In various embodiments, the switches Q1 and/or Q2 are transistors, such as Field-Effect Transistors (FETs), such as Metal Oxide Semiconductor Field-Effect Transistors (MOSFETs), e.g., n-channel FET, such as NMOS. Frequently, the second electronic switch Q2 is also implemented just with a diode, where the anode is connected to the terminal 200b and the cathode is connected to the switching node Lx.

In the embodiment considered, a low-pass filter LPF is intermediate the switching node Lx and the output terminal 202a.

For instance, the low-pass filter LPF comprises: an inductive element L, such as an inductor, coupled (e.g., directly) between the switching node Lx and the (positive) output terminal 202a, and a capacitor C coupled (e.g., directly) between the output terminals 202a and 202b.

As exemplified in FIG. 2, the (negative) output terminal 202b is coupled (e.g., directly) to the (negative) input terminal 200b.

As exemplified in FIG. 2, output terminals 202a and 202b are coupled via a feedback network (e.g., voltage divider R_up, R_down) configured to provide a feedback voltage V_{FB} as a scaled replica of the output voltage Vₒᵤₜ

As exemplified in FIG. 2, the electronic switches Q1, Q2 are configured to be driven by respective control signals DRV1, DRV2 produced via a controller circuit 10. For instance, a second control signal DRV2 for the second electronic switch Q2 may be obtained by inverting (e.g., via a NOT gate 201) a first control signal DRV1.

As exemplified in FIG. 2, a controller circuit 100 comprises: a first control circuit 30, such as a pulse-width modulated (PWM) peak-current mode (PCM) control circuit, suitable for use in a first operating mode or regime of the converter 20a, such as a continuous current mode (CCM) or a discontinuous current mode (DCM) operating regime; a second control circuit 40, such as a pulsed-frequency modulated (PFM) constant ON-time (COT) control circuit, suitable for use in a second operating mode or regime of the converter 20a, such as a light load regime; and a mode selection circuit 50, such as a comparator circuit 500 configured to provide a trigger signal JUMP2COT to trigger the control unit MCU to assert or de-assert the enable signals EN_PCM, EN_COT to enable the first or the second control circuits 30, 40 to drive the switching circuit Q1, Q2, as discussed in the following.

As exemplified in FIG. 2, a logic unit MCU, such as a microcontroller, is coupled to the controller circuit 100 to provide thereto one or more activation signals, such as a first enable signal EN_PCM configured to activate/deactivate the first control circuit 30 and/or a second enable signal EN_COT configured to activate/deactivate the second control circuit 40.

As exemplified in FIG. 2, the first control circuit 30 comprises: a first error amplifier circuit 300 comprising a first input node 300a coupled to a reference voltage level V_{REF}, a second input node 300b coupled to the feedback network R_up, R_down to receive the feedback voltage V_{FB} therefrom; the first error amplifier circuit 300 is configured to provide a difference signal Vc at an output node 300c as a difference among the feedback voltage V_{FB} and the reference voltage level V_{REF}; a PCM circuit 302 coupled to the first comparator circuit 300 to receive the first comparator signal Vc and coupled to the control unit MCU to receive the enable signal EN_PCM, the PCM circuit 302 configured to produce a PWM control signal PWM1 for the switching circuit Q1, Q2 when the first enable signal EN_PCM is asserted; preferably, a clamping circuit (CC) 304 interposed the first comparator circuit 300 and the PCM circuit 302, the clamping circuit 304 configured to apply voltage clamping to the first comparison signal Vc, to limit a voltage value of the comparison signal Vc, for instance in order to maintain a same voltage level of the second control circuit 40, as discussed in the following.

As exemplified in FIG. 2, the second control circuit 40 comprises: a second comparator or error amplifier circuit 400 comprising a first input node 400a coupled to a reference voltage level V_{REF}, a second input node 400b coupled to the feedback network R_up, R_down to receive the feedback voltage V_{FB} therefrom; the second error amplifier circuit 400 is configured to provide a comparison or difference signal V2 at an output node 400c as a difference among the feedback voltage V_{FB} and the reference voltage level V_{REF}; and a timing circuit 402 coupled to the second comparator circuit 400 to receive the comparison signal V2 and coupled to the control unit MCU to receive the second enable signal EN_COT, the timing circuit 402 configured to produce a timing signal for the switching circuit Q1, Q2 when the second enable signal EN_COT is asserted.

As exemplified in FIG. 2, the mode selection circuit 50 comprises a third comparator circuit 500 having a first input node 500a coupled to the reference voltage level V_{REF},a second input node 500b coupled to the feedback network R_up, R_down to receive the feedback voltage V_{FB} therefrom; the third comparator circuit 500 is configured to perform a comparison of the feedback voltage V_{FB} and the reference voltage level V_{REF},providing a trigger signal JUMP2COT at an output node 500c as a result of the comparison.

It is noted that the functions discussed in relation to separate and distinct circuits 300, 400, 500 may actually relate to a same circuit shared among the various control circuits 30, 40, 50 to perform the error amplifier/comparator operations in one or more embodiments.

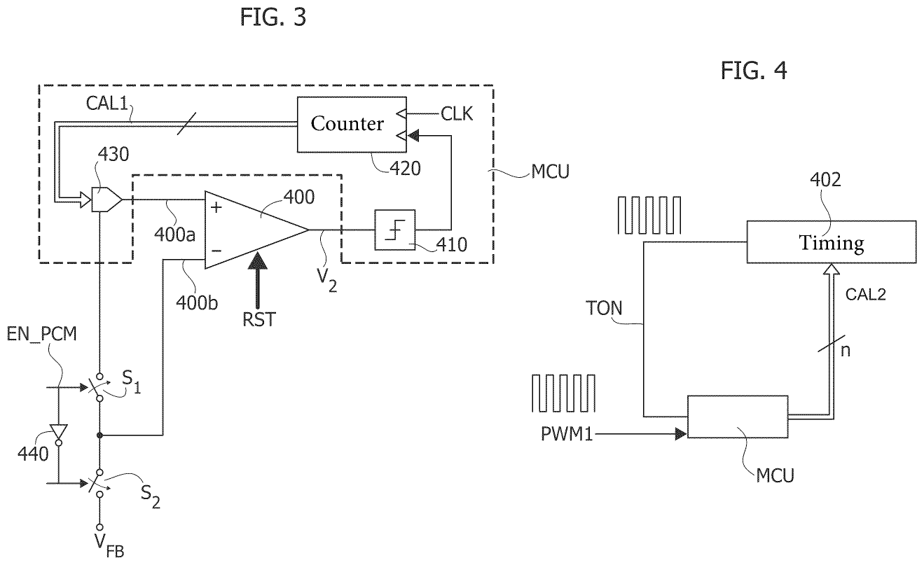

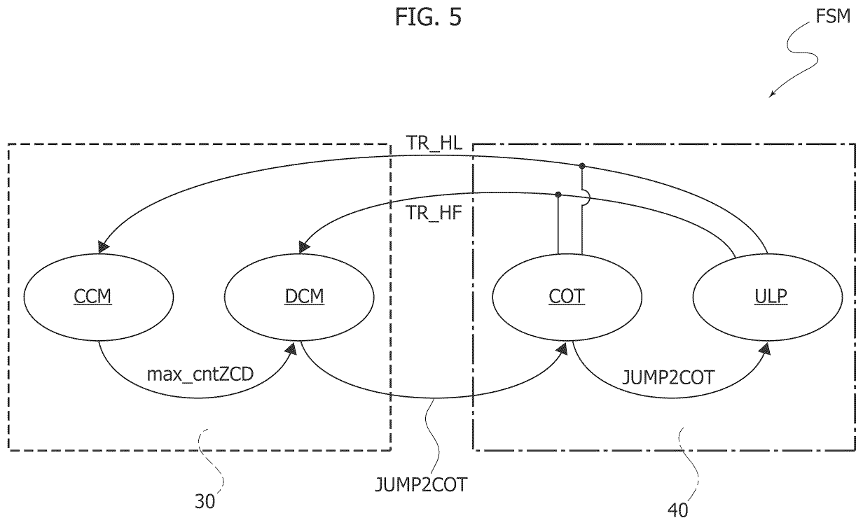

FIGS. 3 and 4 are exemplary of portions of the second control circuit 40.

As exemplified in FIG. 3, a method as per the present disclosure comprises calibrating at least one of the second comparator 400 and the timing circuit 402 of the second circuit 40 while the first control circuit 30 is enabled, e.g., in response to the control unit MCU asserting the first enable signal EN_PCM.

Performing a calibration operation of the second control circuit 40 at the beginning of an operating phase in which the first circuit 30 drives the switching circuit Q1, Q2 facilitates continuous operation thereof in providing an output signal to the load.

As exemplified in FIG. 3, calibrating the comparator circuit 400 of the second control circuit 40 comprises compensating an offset of the comparator circuit 400.

As exemplified in FIG. 3, the offset non-ideality of the comparator 400 is modeled as a voltage generator Voff coupled to the second input node 400b of the comparator.

In order to compensate such an offset, the comparator 400 may comprise a dedicated offset compensation circuitry or it may be coupled to the control logic MCU that comprises internal circuitry configured to perform the calibration.

As exemplified in FIG. 3, the offset calibration circuitry comprises: a first switch S1 interposed the first input node 400a and the second input node 400b of the comparator 400, the first switch S1 configured to be driven between a first “ON” or “closed” state in response to the enable signal EN_PCM being asserted and a second “OFF” or “open” state in response to the enable signal EN_PCM being de-asserted; a second switch S2 interposed the second input node 400b of the comparator 400 and the feedback node VFB, the second switch S2 configured to be driven between a first “ON” or “closed” state in response to an inverted version 440 of the enable signal EN_PCM being asserted and a second “OFF” or “open” state in response to the inverted version 400 of the enable signal EN_PCM being de-asserted; an edge detector circuit 410 coupled to the output node 400c of the comparator circuit 400, the edge detector circuit 410 configured to detect when the comparison signal V2 output by the comparator switches from a first (e.g., “low” or “0”) logic level to a second (e.g., “high” or “1”) logic level; a counter 420 coupled to the edge detector circuit 410 and configured to increase a digital calibration signal CAL1 until the edge detector detects a change in the comparison signal V2; and a digital to analog converter, DAC circuit 430 coupled to the counter 420 to receive the digital calibration signal CAL1 therefrom and coupled to the first input node 400a of the comparator circuit 400 to provide thereto a signal (e.g., a voltage) based on the digital calibration signal CAL1.

As exemplified in FIG. 3, the offset calibration method comprises: in response to the enable signal EN_PCM being asserted, coupling the first input node 400a and the second input node 400b therebetween; and increasing the digital calibration signal CAL1 by the counter 420 until the comparison signal V2 jumps to the second logic value, thereby indicating that the input offset voltage Voff has been compensated.

As exemplified in FIG. 3, once the counter 420 has reached the value of the digital calibration signal CAL1 that triggers the edge detector 410, the counter 420 becomes a working register to store such a value. For instance, upon a next operating cycle in which the second control circuit 40 drives the switching circuit Q1, Q2, the digital calibration signal value is retrieved from the counter to maintain the offset Voff of the comparator 400 compensated when comparing the feedback voltage V_{FB} and the reference voltage V_{REF}. For instance, the stored value of CAL1 may be reset at a subsequent assertion of the enable signal EN_PCM by the control unit MCU, facilitating a fine tuning of the offset calibration.

In an alternative scenario, the MCU may comprise different offset calibration circuitry to perform the offset calibration method as discussed herein. For instance, a method known as successive approximation method (SAR) may be suitable for use in one or more alternative scenarios. For instance, article “How does successive approximation sar adc work and where is it best used” accessible from Circuit Digest (circuitdigest.com), and incorporated herein by reference, discusses an exemplary circuit to perform SAR.

As exemplified in FIG. 4, the timing circuit calibration comprises configuring the timing circuit 402 to produce a driving signal TON with a time duration (specifically, an ON-time duration T_{ON}) matching the duration of the (ON-time duration of the) driving signal PWM1 produced by the first control circuit 30 at the beginning of enabled operation thereof. This facilitates having the same amount of energy provided to the output load 30 (thanks to timing calibration) when switching from one control circuit 30 to another 40, optionally together with the same ripple of the output voltage Vₒᵤₜ (thanks to offset compensation of the comparator 400 as exemplified in FIG. 3). An arrangement as exemplified in FIGS. 3 and/or 4 facilitates improving continuity of operation while alternating control circuits 30, 40 driving the switching circuit Q1, Q2.

As exemplified in FIG. 4, the timing circuit 402 is coupled to a control unit (e.g., the microcontroller MCU) to receive therefrom a second calibration signal CAL2 (e.g., n-bit signal) based on the signal TON output by the timing circuit 400 and of the driving signal PWM1 output by the first control unit 30.

For instance, the control unit MCU may perform the calibration of the on-time TON exemplified in FIG. 4 in a manner like that discussed with respect to the offset voltage Voff in FIG. 3: in other words, in order to bring the TON signal in line with the PWM1 signal it may be possible to use a counter (e.g., equipped on-board the control unit MCU) to produce the second digital word CAL2 to adjust the timing circuit 402 to vary the time duration of the ON time of the timing signal TON. For instance, the calibration exemplified in FIG. 4 may also exploit a SAR method as discussed in the foregoing.

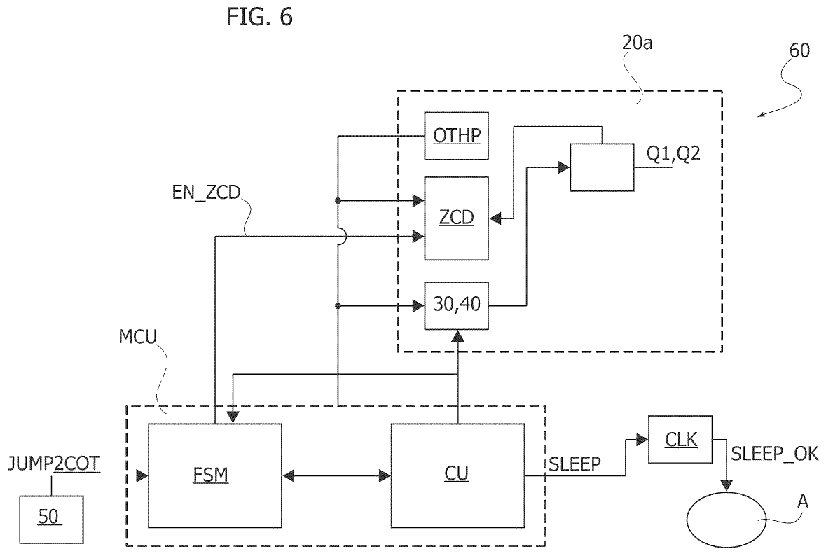

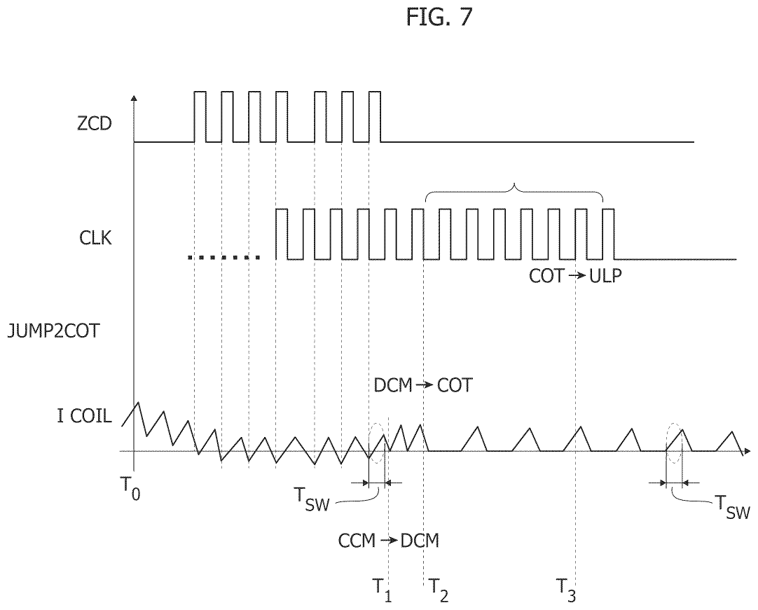

As exemplified in FIGS. 5 and 6, the control unit MCU may be configured to drive enabling the first or the second control circuit 30, 40 to provide the respective first or second control signals PWM1, TON to the switching circuit Q1, Q2 according to a method encoded as a finite-state machine, FSM equipped on-board (e.g., in a data storage portion of) the control unit MCU.

FIG. 5 is a diagram exemplary of the FSM equipped on-board the control unit MCU.

As exemplified in FIG. 5, the finite state machine FSM comprises four states: a first state CCM and a second state DCM in which the switching circuit Q1, Q2 is driven by the first control circuit 30; and a third state COT and a fourth state ULP in which switching circuit Q1, Q2 is driven by the second control circuit 40.

The way in which the first and second circuits 30, 40 are operated in each state CCM, DCM, COT and ULP of the FSM is discussed in the following, in particular with reference to FIGS. 6 to 14.

FIG. 6 is exemplary of a simplified block diagram of a device 60 suitable for use in one or more embodiments of the electronic converter circuit 20a.

As exemplified in FIG. 6, the device 60 comprises the control unit MCU coupled to the electronic converter 20a and to service circuitry such as a clock generator circuit CLK and other user circuits A.

As exemplified in FIG. 6, the control unit MCU comprises a data storage unit FSM configured to store the transition rules of the finite state machine and a processing unit CU configured to process signals involved in the control method for the electronic converter 20a.

For instance, the logic unit MCU comprises a microcontroller or an ASIC/FPGA circuit.

As exemplified in FIG. 6, the electronic converter hardware 20a may further comprise, in addition to 30, 40, 50 and Q1, Q2 already discussed, also other circuit such as: a zero-crossing detector circuit ZCD configured to sense, when activated via the ZCD enable signal EN_ZCD, a current at the switching node Lx of the switching circuit Q1, Q2 and to assert a corresponding detection signal in case an inversion of polarity of the current at the switching node Lx is detected; other peripheral circuits OTHP, such as for instance alarm generating circuitry, which may be activated or de-activated based on control signals from the control unit MCU; and a clock generator circuit CLK coupled to the control unit MCU to provide a synchronization clock signal CLK, for instance for control loop circuits 30, 40 and/or other user circuits A.

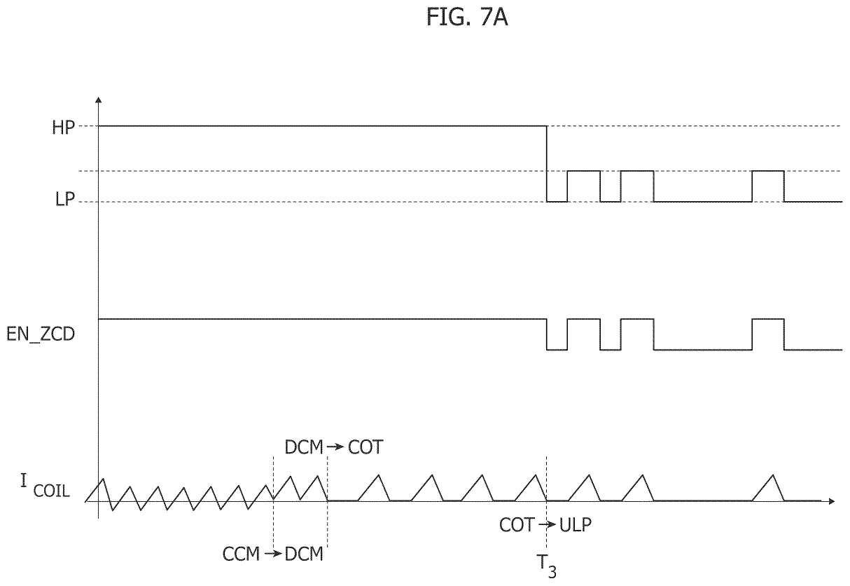

As exemplified in FIG. 7, a method of varying the mode of operation of the circuit 20a from the first (e.g., “high” power) operating mode CCM to the fourth (e.g., “low” power) operating mode ULP comprises: during a first time interval T₀-T₁, detecting an electric current ICOL flowing in the filter circuit LPF, and counting an integer number N (e.g., N=7 in FIG. 7) of zero-crossing events of the current signal ICOL, in a manner per se known, for instance using the ZCD detector circuit ZCD equipped on the control unit MCU; at lapse of the first time interval T₀-T₁, asserting an overflow signal max_cntZCD to a first logic value (e.g., “1” or “true”) and switching from a first state CCM to a second state DCM in response to the overflow signal max_cntZCD being asserted; for instance, if the ZCD events are not consecutive, the detector circuit ZCD is reset after two missed zero-cross detection events; at time instant T2, in response to the mode selection circuit 50 asserting the JUM2COT signal, switching operation from DCM to COT by deactivating (EN_PCM= “0” or “false”) the first control circuit 30 and activating (EN_COT=“1” or “true”) the second control circuit 40; during the time interval T2-T3, comparing the switching frequency or period Tsw of the timing signal T_{ON} with a frequency/period of an internal clock signal CLK (e.g., equipped on board the device 60 comprising the control unit MCU); for a pre-defined integer number of clock cycles M (e.g., M=8 in FIG. 7), monitoring the frequency or period of the timing signal TON and comparing the monitored frequency/period to the internal clock frequency/period; and at lapse of the time interval T2-T3, in response to detecting that the frequency or period Tsw of the timing signal TON is lower than the frequency/period of the internal clock signal CLK for the entire length of the pre-defined integer number M of clock cycles, switching operation from the third state COT to the fourth state ULP.

As exemplified in FIG. 7, thanks to the calibration operation(s) exemplified in FIG. 4 (and optionally also FIG. 3), the on-time fraction TSW of the switching period of the current signal ICOIL in the first CCM state is equal to that of the signal in the fourth state ULP, thereby providing a smooth operation of electronic device 20a.

As exemplified herein, in the fourth status ULP, some of the circuit of the device 60 exemplified in FIG. 6 may be turned off in order to reduce energy consumption.

For instance, the circuits OTHP and CLK are turned off, leaving a residual consumption of 900 nA to pre-bias nodes to be fast enough during turn on phase.

As exemplified in FIGS. 6 and 7A: a low power signal LP is sampled by the digital circuit DIGITAL of the MCU, for instance after a delay of one clock cycle from the transition to ULP; in response to the ULP state being reached at time instant T3, the control unit MCU interrupts the internal clock CLK, as well as startup circuits A and pre regulated voltages OTHP, with a minimal residual consumption (e.g., around 7.4 microAmpere); at the same time, the MCU maintains asserted the second enable signal EN_COT (e.g., with a total consumption of 800 nA); the zero cross detector circuit ZCD may be periodically disabled and activated only at rising edges of the coil current ICOIL; specifically, the enable signal EN_ZCD is asserted for a time equal to Ton+Toff while the timing circuit 402 is turned on and off every Ton; and the signals HP and LP represent the high power mode and low power mode of operating switching transistors Q1, Q2.

For instance, the overall consumption of the control logic MCU in such a ULP “idle” mode is 9.6 microAmperes, in addition that of the switching circuit 20a is about 500 nanoAmperes from power stage Q1, Q2.

As exemplified in FIGS. 5 to 9, a method of varying the mode of operation of the circuit 20a from the second (e.g., “low” power LP) operating mode 40 to a second (e.g., “high” power HP) operating mode 30 comprises: in response to failing to detect three consecutive ZCD events, asserting a full transition signal TR_HL-this is indicative of the output load being high enough to restore CCM mode operation, going from the fourth state ULP to the first state CCM in the FSM; otherwise, during low power constant-on time operation (third state COT of the FSM), in response to detecting, e.g., at time interval T4, that a switching frequency is higher than the frequency of the internal clock signal CLK, the system jumps to the second state DCM.

As exemplified in FIG. 5, this latter transition is denoted by arrow TR_HF.

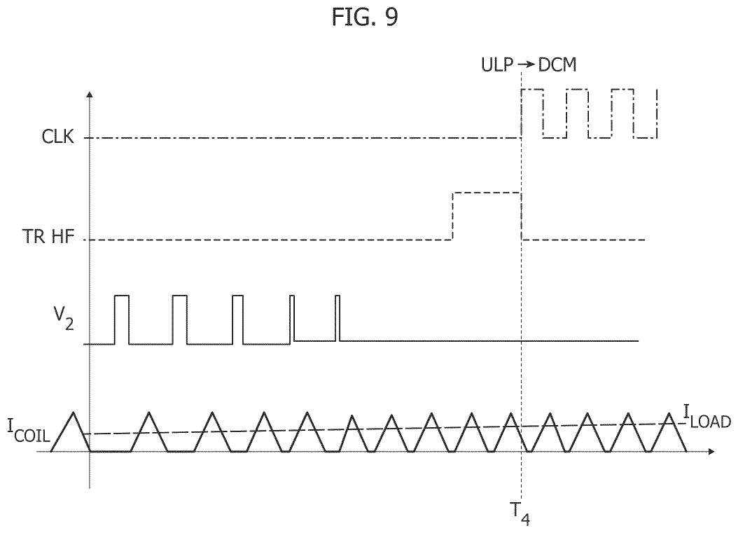

As discussed in the foregoing and exemplified in FIG. 9, during operation in the fourth mode ULP, the internal clock signal CLK is turned off. Therefore, the transition TR_HF is possible thanks to a time window generated at each Ton and calibrated, in CCM or DCM mode states, to be equal to one clock cycle of the internal clock CLK, for instance.

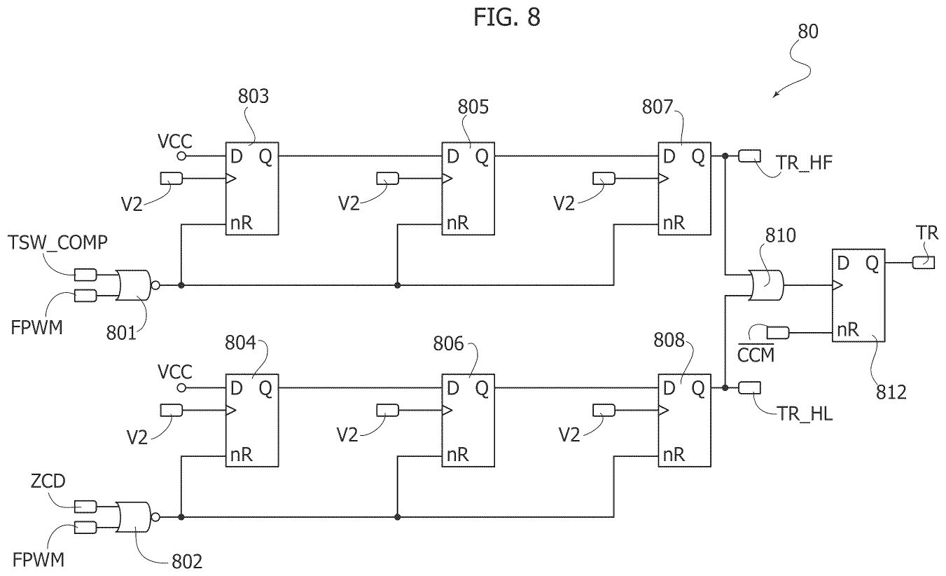

FIG. 8 is a diagram exemplary of a logic circuit 80 dedicated to manage signals during the TR_HF transition.

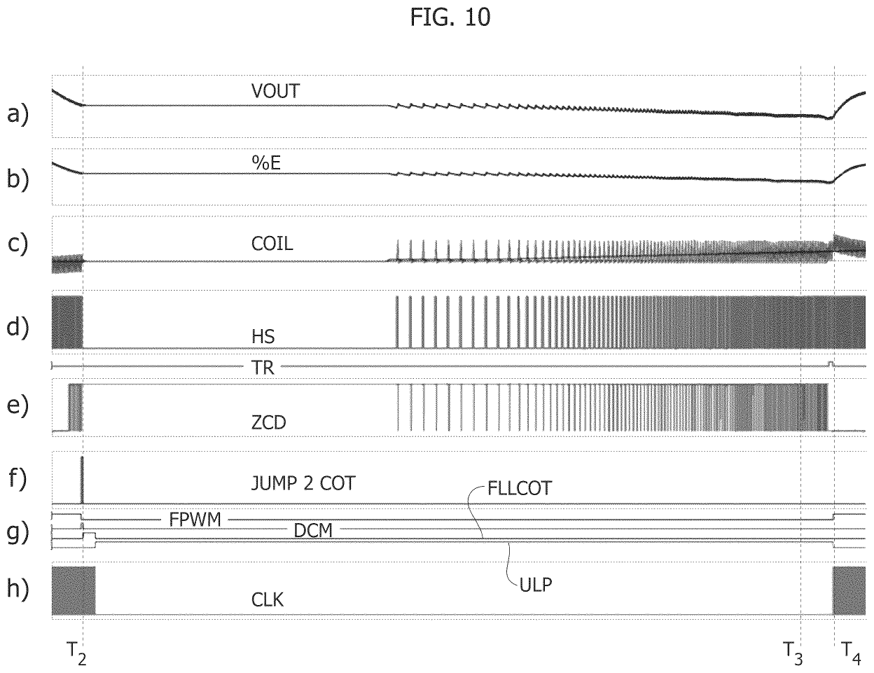

For instance: either high switching frequency leads to move from the third COT state to the second DCM state, as exemplified in FIG. 9—this is the case when the second comparator 400 is calibrated to switch at the internal clock frequency; or there is a high load transition from the third state COT to the first state CCM as exemplified in FIG. 10, in case the current load is high enough to let the system work in CCM region.

As exemplified in FIG. 8, a logic circuit 80 configured to perform the transition from the second operating mode to the first operating mode comprises: a first signal processing chain 801, 803, 805, 807 comprising a first NAND circuit 801 coupled to a set of memory elements (e.g., flip flops) 803, 805, 807, the first processing chain 801, 803, 805, 807 configured to provide the trigger signal TR_HF for the transition from the fourth state ULP or the third state COT to the first state CCM; a second signal processing chain 802, 804, 806, 808 comprising a second NAND circuit 802 coupled to a further set of memory elements (e.g., flip flops) 804, 806, 808, the second processing chain 802, 804, 806, 808 configured to provide the trigger signal TR_HL for the transition from the fourth state ULP or the third state COT to the first state CCM; a combinatorial logic gate 810, such as an AND gate, coupled to the first processing chain 801, 803, 805, 807 and to the second processing chain 802, 804, 806, 808 to combine trigger signals TR_HF, TR_HL and determine the transition to perform; and a further memory circuit 812 (e.g., a flip-flop) configured to sample the result of the combinatorial logic gate 810, producing a general trigger signal TR which can be provided to the control unit MCU.

As exemplified in FIGS. 5 to 10, as soon as the TR_HL signal is asserted, the transition from low power to high power mode starts. For instance, the first control circuit 30 is enabled via the respective enable signal EN_PCM. At the same time, the general trigger signal TR may reset sleep signal provided to the oscillator in the main logic, startup bias and pre regulators of the MCU. For instance, during this interval, even if the general trigger signal TR is received, the second control circuit 40 is active. When the first clock cycle arrives, to the synchronous state machine, the PCM loop 30 takes the control of the regulation. As a result of performing calibration as exemplified in FIGS. 3 and 4, the boundary between DCM and CCM is the same for the second control circuit 40 and the first control circuit 30. Therefore, if the trigger signal TR_HL enables the respective state transition, this is the result of the load reaching a threshold to keep the system in CCM and so in PCM loop, for instance. In this way, bounces between control loops may be countered. In case of a fast load transition occurring, for instance from “low” to “high” load, the second circuit 40 may be active to recovery Vout undervoltage. For instance, even if the first PCM circuit 30 keeps working after a certain amount of time from TR HL event, the second COT circuit may be able to respond also to this kind of load variation.

In one or more embodiments, a transition triggered by the TR_HF signal or by the TR_HL signal may consume substantially a similar amount of power.

As exemplified in FIGS. 2 to 10, the first control circuit 30 and the second control circuit 40 may alternatively be activated by respective activation signals. For instance, in response to the further comparator 500 asserting the further comparison signal JUMP2COT with a first (e.g., “1” or “true”) logic value, the first circuit 30 is turned off; optionally, the first comparison signal Vc is clamped to the bottom voltage range allowed at the output of the error amp; at the same time, the second control circuit 40 operates until transition event occurs (e.g., TR_HL or TR_HF signals are asserted). However, in response to a TR event, the first control circuit 30 is turned on, but the PCM circuit 302 does not take the control until the first clock cycle arrives; in response to the first clock cycle, the PCM loop start to drive the switching circuit Q1, Q2 while the second control circuit 40 performs a calibration.

As exemplified in FIGS. 2 and 3, the first 300 and second 400 comparators share a same feedback VFb and voltage reference VREF and they are enabled and disable by a synchronous state machine encoded in the control circuitry MCU, 500.

FIG. 10 comprises portions a) to h) showing time diagrams of a transitions, from high power to low power and back, for instance while the system operates in a further low noise mode.

As exemplified in portion b) of FIG. 10, an error signal % E is indicated that an amount of error at the output regulated voltage for a transition between CCM and DCM (that is, alternating from the first control circuit 30 to the second control circuit 40) remains low, e.g., lower than 0.5%.

As exemplified in portions e) and f) of FIG. 10, in response to a certain count of ZCD events represented by the ZCD signal and in response to assertion of the further comparison signal JUMP2COT, the control circuit MCU drives transition from CCM operating mode to COT operating time, by activating the second control circuit 40 and deactivating the first control circuit 30.

As exemplified in portions d) and g) of FIG. 10, in response the transition signal TR being asserted, the control circuit MCU drives transition from COT operating mode to CCM operating time, by activating the first control circuit 30 and calibrating the second control circuit 40.

As exemplified in portion h) of FIG. 110 during the time interval T2-T4, that is during operation in the first “low power” mode, the internal clock signal CLK is de-asserted or turned off, with other circuits, to have an overall reduced power consumption (e.g., about 9.6 microAmps) in such an “idle” phase.

For instance, during operation of the first control circuit 30, an on-time duration TON may have a first value, (e.g., about 300 ns, with 1 ns=10⁻⁹s=1 nanosecond), and the second control circuit may set an on-time duration TON equal to a second value (e.g., 343 ns) slightly higher than the first value in to confirm the transition between one to the other one loop.

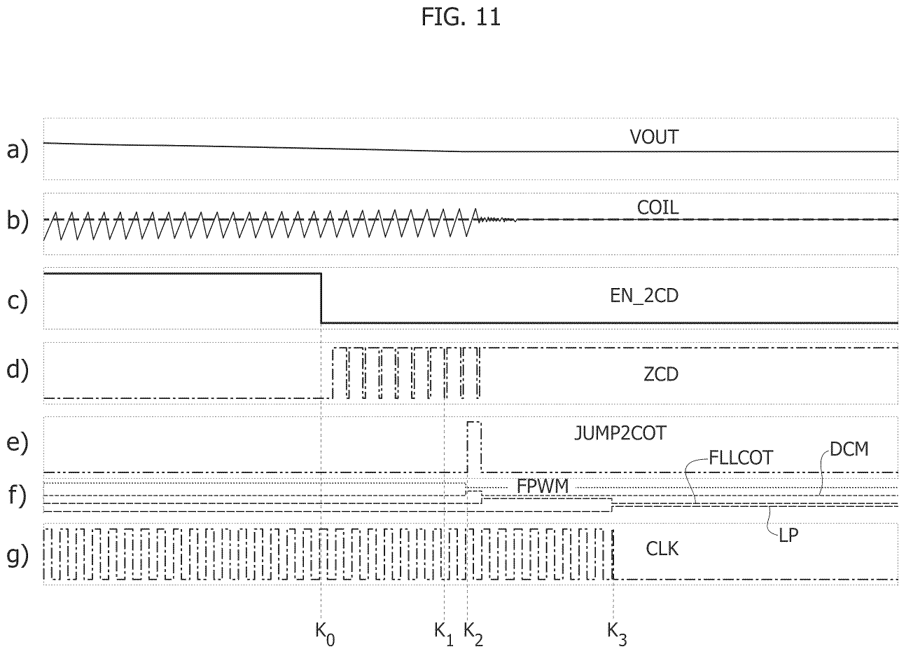

As exemplified in FIG. 11, in a first exemplary scenario the high-power to low power operating mode transitions comprises: at a first time instant K₀, asserting an enable zero-crossing detection signal EN_ZCD with a first (e.g., “1” or “high”) logic value which triggers a counter (e.g., equipped on board the control unit MCU) to count the number of times that the coil current (represented in portion b of FIG. 11) crosses the zero; at a second time instant K₂, in response to the ZCD counter equipped on-board the MCU reaching a given number (e.g., seven) at K₁ as a precondition and in response to the further comparison signal JUMP2COT being asserted with the first logic value, the switching circuit Q1, Q2 is driven by the second control circuit 40 in place of the first control circuit 30; at a third time instant K₃, in response to switching frequency during operation by the second control circuit 40 is lower than the internal clock frequency, the system goes in low power mode ULP, turning off the internal clock generator and most of the internal circuit.

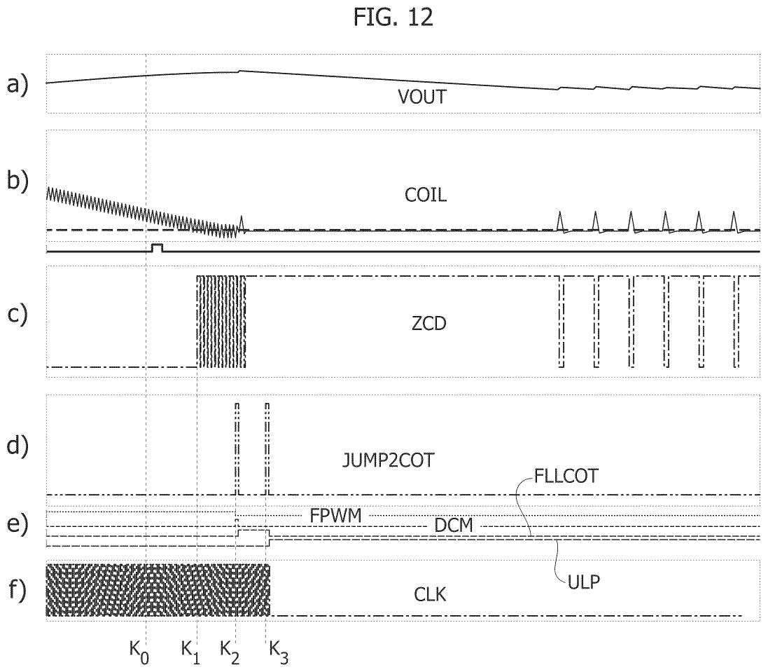

As exemplified in FIG. 12, in a second exemplary scenario the transition from high power to low power (e.g., when the load current COIL goes from 3 A to 100 mA, while the system works in low current mode) comprises: at a first time instant K₁, in response to the load current COIL reaching a boundary value at K₀, zero crossing detection counter starts to count the number of times that the coil current cross the zero; at a second time instant K₂, when at least a given number (e.g., 7) ZCD events occur consecutively, the system goes from CCM to DCM operation mode; in response to the further comparison signal JUMP2COT being asserted with the first logic value, the operation of the switching circuit D1 is handover from the first control circuit 30 to the second control circuit 40; at a fourth time instant K₃, in response to the COT switching frequency being lower than the clock internal frequency, the system goes in ultra-low power mode ULP turning off the oscillator CLK and most of the internal circuit.

For instance, during an on-time phase of the driving signal TON produced by the second control circuit 40, ton generator is turned on and ZCD is turned on for a time equal to Ton+Toff.

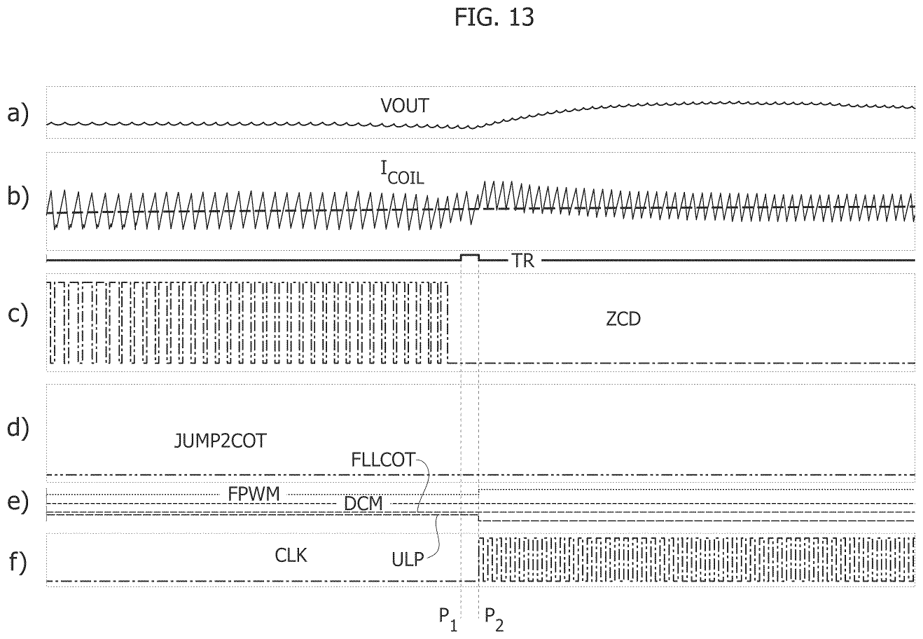

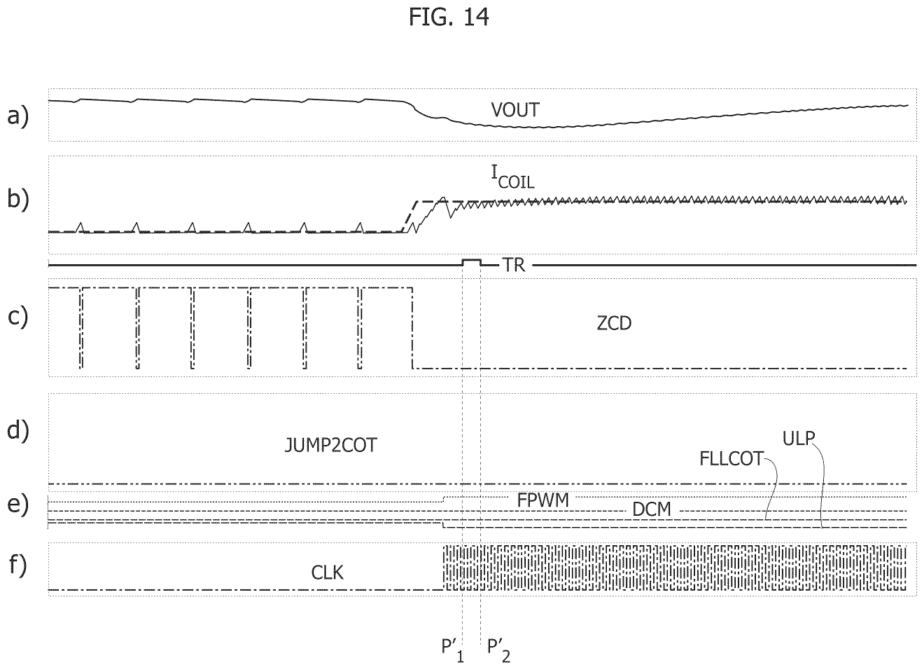

As exemplified in FIG. 13, when going from the “low power” mode to a “high power” mode: as exemplified in portion b) of FIG. 14, when the load current constantly increases, the system operation moves from DCM to CCM; in response to the boundary of the two operation modes being reached, the ZCD comparator goes to zero, and in response to a certain number (e.g., three) of missed ZCD detections while the system is in the ULP state of the FSM, the TR HL signal is asserted high by the control unit MCU (e.g., at time instant P₁); in response to de-assertion of the transition signal TR, for instant at time instant P₂ as exemplified in FIG. 13, the COT loop 40 performs calibration and PCM loop 30 is enabled to start driving the switching circuit Q1, Q2.

As exemplified in portion b) of FIG. 13, since the Ton during operation by the second control circuit 40 is almost equal to the Ton in PCM (thanks to the calibration operation), the discontinuity in coil current is negligible.

As exemplified in portion a) of FIG. 13, the output voltage Vₒᵤₜ has a small perturbation during the transition from the fourth ULP state to the second DCM state.

As exemplified in FIG. 14, when the load current suddenly increases (e.g., from 100 mA to 4A, as exemplified in portion b) of the Figure), the FSM drives the operation to quickly switch from ULP to CCM in response to: at time instant P₁′, missing ZCD detection for a certain number (e.g., three) of Ton time intervals while the device 60 is in the ULP state, so that the transition signal TR HL is asserted high by the control unit MCU; in response to lapse of the time to restart the circuit that were deactivated during the idle ULP phase, the clock signal CLK restarts; at time instant P₂′, when the rising edge of the clock signal CLK is detected, the second control circuit 40 goes under calibration while the first control circuit 30 is enabled and the PCM loop takes the control of the switching circuit Q1, Q2.

As exemplified in portion a) of FIG. 14, despite the sudden change of load values, the variation of output voltage Vₒᵤₜ is contained (e.g., about 2%).

As exemplified herein, a control circuit 100 for an electronic converter device 20a comprises at least one electronic switch Q1, Q2 having a current flow path therethrough configured to be made conductive in response to a drive signal DRV1, DRV2 received at a control node having a first value and to be made non-conductive in response to the drive signal having a second value, where the at least one electronic switch is coupled to an inductive circuit element LPF with an output current ICOIL flowing through the inductive circuit element and where the electronic converter device is configured to provide, via two output nodes 202a, 202b, an output voltage Vₒᵤₜ based on an input voltage Vᵢₙ supplied to the at least one switching transistor.

In a first exemplary scenario, the control circuit 100 comprises: an output node configured to be coupled to said control node of said at least one electronic switch to provide said drive signal thereto; an input node configured to receive a feedback signal V_{FB} indicative of said output voltage; two further input nodes configured to be coupled to said two output nodes of said electronic converter device; and a first driving circuit 30 coupled to the input node of the control circuit to receive the feedback signal. The first driving circuit comprises: a first enable node configured to receive a first enable signal EN_PCM; and a pulse-width modulated, PWM signal generator circuit (02 configured to provide a PWM drive signal PWM1 to said output node of the control circuit in response to said first enable signal being asserted, the PWM drive signal being a function of a difference among the feedback voltage and a first reference voltage level. A second driving circuit 40 is coupled to the input node of the control circuit to receive the feedback signal. The second driving circuit comprises: a second enable node configured to receive a second enable signal EN_COT; and a pulse-frequency modulation, PFM signal generator circuit 402 configured to provide a PFM drive signal TON to said output node of said control circuit in response to said second enable signal being asserted, the PFM drive signal being a function of a difference 400 among the feedback voltage and a second reference voltage level VREF. Logic circuitry MCU, 60 is coupled to the first driving circuit and to the second driving circuit, the logic circuitry (MCU, 60) being configured to assert at least one of the first enable signal (EN_PCM) and the second enable signal (EN_COT). A comparator 500 has a first comparator input node 500a coupled to a third reference voltage level and has a second comparator input node 500b coupled to said output node of the control circuit to receive the feedback voltage, where the comparator is configured to perform a comparison of the feedback voltage and the third reference voltage level and to provide a mode selection signal at a comparator output node 500c as a result of the comparison.

For instance, the logic circuitry is configured to de-assert the first enable signal and to assert the second enable signal in response to the mode selection signal JUMP2COT being asserted.

In a second exemplary scenario, the control circuit further comprises: zero cross detection circuitry ZCD coupled to the two further input nodes of the control circuit and configured to assert a zero cross detection signal in response to detecting a zero value of the output current flowing through the inductive circuit element of the electronic converter device; and timing circuitry CLK configured to provide an internal clock signal with an internal clock period.

In the second example considered, the logic circuitry MCU, 60 is configured to assert the first enable signal EN_PCM in response to: the zero cross detection circuitry failing to assert the zero cross detection signal EN_ZCD for a time interval equal to an integer number, preferably equal to three, of periods of the internal clock signal; or a period of the PFM drive signal being lower than the period of the internal clock signal.

Still in the second exemplary scenario, for instance, the logic circuitry is configured to disable EN_ZCD, SLEEP the zero cross detection circuitry and the timing circuitry CLK while the second enable signal is asserted and in response to the period of the PFM drive signal being lower than the period of the internal clock signal for a monitoring time interval equal to an integer number, preferably eight, of clock periods.

In a third exemplary scenario, the control circuit comprises: zero cross detection circuitry coupled to the two further input nodes of the control circuit and configured to assert a zero cross detection signal EN_ZCD in response to detecting a zero value of the output current flowing through the inductive circuit element of the electronic converter device, wherein the logic circuitry is configured to assert the second enable signal in response to the zero cross detection circuit asserting the ZCD signal for an integer number, preferably equal to seven, of consecutive times.

As exemplified herein, the first control circuit (30) comprises: an error amplifier 400 having a first amplifier input node 400a coupled to the first reference voltage level and having a further amplifier input node 400b coupled to said second node of the control circuit, the error amplifier circuit 50 configured to provide a first error amplifier signal Vc based on a difference among the feedback voltage and the first reference voltage level; and a clamp circuit 304 configured to limit a voltage level of the first error amplifier signal.

As exemplified herein, the logic circuitry is configured to calibrate the PFM signal generator circuit 402 to set a duty cycle Tsw of the PFM drive signal TON equal to the duty cycle of the PWM drive signal PWM1 in response to asserting the first enable signal EN_PCM.

As exemplified herein, the second control circuit 40 comprises a comparator circuit 400 comprising a first comparator input node 400a coupled to the second reference voltage level, a second comparator input node 400b coupled to the input node of the control circuit to receive the feedback voltage, the comparator circuit configured to provide at an output node 400c a comparison signal V2 based on a comparison of the feedback voltage and the reference voltage level.

For instance: the comparator circuit of the second control circuit further comprises a reset node RST configured to reset the comparison signal; and the logic circuitry is configured to provide to the comparator circuit an offset calibration signal CAL1, CAL2 m as a function of the comparison signal in response to asserting the first enable signal.

As exemplified herein, the first reference voltage, the second reference voltage and the third reference voltage are equal to a same reference voltage.

An electronic device 20a as exemplified herein, for instance, comprises: at least one electronic switch Q1, Q2 having a current flow path therethrough configured to be made conductive in response to a drive signal DRV1, DRV2 received at a control node having a first value and to be made non-conductive in response to the drive signal having a second value; an inductive circuit element LPF coupled to the at least one electronic switch with an output current ICOL flowing through the inductive circuit element LPF; an input voltage Vin supplied to the at least one switching transistor; two output nodes 202a, 202b coupled to the inductive circuit element; and a control circuit 100 according to the present disclosure coupled to the inductive circuit element, to the two output nodes and to the at least one electronic switch, the control circuit configured to drive the electronic converter device to provide to an electric load 30 an output voltage based on the input voltage supplied to the at least one switching transistor.

It will be otherwise understood that the various individual implementing options exemplified throughout the figures accompanying this description are not necessarily intended to be adopted in the same combinations exemplified in the figures. One or more embodiments may thus adopt these (otherwise non-mandatory) options individually and/or in different combinations with respect to the combination exemplified in the accompanying figures.

The claims are an integral part of the technical teaching provided herein with reference to the embodiments.

Without prejudice to the underlying principles, the details and embodiments may vary, even significantly, with respect to what has been described by way of example only, without departing from the extent of protection. The extent of protection is defined by the annexed claims.

1. A control circuit for an electronic converter device comprising at least one electronic switch having a current flow path therethrough configured to be made conductive in response to a drive signal received at a control node having a first value and to be made non-conductive in response to the drive signal having a second value, wherein the at least one electronic switch is coupled to an inductive circuit element with an output current flowing through the inductive circuit element, wherein the electronic converter device is configured to provide, via two output nodes, an output voltage based on an input voltage supplied to the at least one switching transistor, the control circuit comprising:
an output node configured to be coupled to said control node of said at least one electronic switch to provide said drive signal thereto;
an input node configured to receive a feedback signal indicative of said output voltage;
two further input nodes configured to be coupled to said two output nodes of said electronic converter device;
a first driving circuit coupled to the input node of the control circuit to receive the feedback signal, the first driving circuit comprising:
a first enable node configured to receive a first enable signal; and
a pulse-width modulation (PWM) signal generator circuit configured to provide a PWM drive signal to said output node of the control circuit in response to said first enable signal being asserted, wherein the PWM drive signal is a function of a difference between the feedback voltage and a first reference voltage level;
a second driving circuit coupled to the input node of the control circuit to receive the feedback signal, the second driving circuit comprising:
a second enable node configured to receive a second enable signal; and
a pulse-frequency modulation (PFM) signal generator circuit configured to provide a PFM drive signal to said output node of said control circuit in response to said second enable signal being asserted, wherein the PFM drive signal is a function of a difference between the feedback voltage and a second reference voltage level;
logic circuitry coupled to the first driving circuit and to the second driving circuit, wherein the logic circuitry is configured to assert at least one of the first enable signal and the second enable signal; and
a comparator having a first comparator input node coupled to a third reference voltage level and having a second comparator input node coupled to said output node of the control circuit to receive the feedback voltage, the comparator configured to perform a comparison of the feedback voltage and the third reference voltage level and to provide a mode selection signal at a comparator output node as a result of the comparison;
wherein the logic circuitry is configured to de-assert the first enable signal and to assert the second enable signal in response to the mode selection signal being asserted.

2. The control circuit of claim 1, further comprising:
zero cross detection circuitry coupled to the two further input nodes of the control circuit and configured, when enabled by an enable signal, to assert a zero cross detection signal in response to detecting a zero value of the output current flowing through the inductive circuit element of the electronic converter device; and
timing circuitry configured to provide an internal clock signal with an internal clock period;
wherein the logic circuitry is configured to assert the first enable signal in response to:
the zero cross detection circuitry failing to assert the zero cross detection signal for a time interval equal to a first integer number of periods of the internal clock signal; or
a period of the PFM drive signal being lower than the period of the internal clock signal.

3. The control circuit of claim 2, wherein the logic circuitry is configured to disable the zero cross detection circuitry and the timing circuitry while the second enable signal is asserted and in response to the period of the PFM drive signal being greater than the period of the internal clock signal for a monitoring time interval equal to a second integer number of periods of the internal clock signal.

4. The control circuit of claim 1, comprising:
zero cross detection circuitry coupled to the two further input nodes of the control circuit and configured to assert a zero cross detection signal in response to detecting a zero value of the output current flowing through the inductive circuit element of the electronic converter device;
wherein the logic circuitry is configured to assert the second enable signal in response to the zero cross detection circuit asserting the zero cross detection signal for an integer number of consecutive times.

5. The control circuit of claim 1, wherein the first control circuit comprises:
an error amplifier having a first amplifier input node coupled to the first reference voltage level and having a further amplifier input node coupled to said second node of the control circuit, the error amplifier circuit configured to provide a first error amplifier signal based on a difference between the feedback voltage and the first reference voltage level; and
a clamp circuit configured to limit a voltage level of the first error amplifier signal.

6. The control circuit of claim 1, wherein the logic circuitry is configured to calibrate the PFM signal generator circuit to set a duty cycle of the PFM drive signal equal to the duty cycle of the PWM drive signal in response to asserting the first enable signal.

7. The control circuit of claim 1, wherein the second control circuit comprises a comparator circuit comprising a first comparator input node coupled to the second reference voltage level, a second comparator input node coupled to the input node of the control circuit to receive the feedback voltage, the comparator circuit configured to provide at an output node a comparison signal based on a comparison of the feedback voltage and the reference voltage level.

8. The control circuit of claim 7, wherein:
the comparator circuit of the second control circuit further comprises a reset node configured to reset the comparison signal; and
the logic circuitry is configured to provide to the comparator circuit an offset calibration signal as a function of the comparison signal in response to asserting the first enable signal.

9. The control circuit of claim 1, wherein the first reference voltage, the second reference voltage and the third reference voltage are equal to a same reference voltage.

10. An electronic device, comprising:
at least one electronic switch having a current flow path therethrough configured to be made conductive in response to a drive signal received at a control node having a first value and to be made non-conductive in response to the drive signal having a second value;
an inductive circuit element coupled to the at least one electronic switch with an output current flowing through the inductive circuit element;
an input voltage supplied to the at least one switching transistor;
two output nodes coupled to the inductive circuit element; and
a control circuit according to claim 1, the control circuit configured to drive the electronic converter device to provide to an electric load an output voltage based on the input voltage supplied to the at least one switching transistor.

11. A control circuit for an electronic converter device, comprising:
an output node generating a drive signal for application to a control node of an electronic switch of the electronic converter device;
an input node configured to receive a feedback signal indicative of an output voltage of the electronic converter device;
a first driving circuit including a pulse-width modulation (PWM) signal generator circuit configured to provide a PWM drive signal to said output node when enabled by a first enable signal, wherein the PWM drive signal is a function of a difference between the feedback voltage and a first reference voltage level;
a second driving circuit a pulse-frequency modulation (PFM) signal generator circuit configured to provide a PFM drive signal to said output node when enabled by a second enable signal, wherein the PFM drive signal is a function of a difference between the feedback voltage and a second reference voltage level;
comparator circuitry configured to compare the feedback voltage and a third reference voltage level and provide a mode selection signal;
logic circuitry configured to control assertion and de-assertion of the first enable signal and the second enable signal, wherein the logic circuitry de-asserts the first enable signal and asserts the second enable signal in response to an assertion of the mode selection signal.

12. The control circuit of claim 11, further comprising:
zero cross detection circuitry configured to assert a zero cross detection signal in response to detecting a zero value of the output current for the electronic converter device; and
timing circuitry configured to provide an internal clock signal with an internal clock period;
wherein the logic circuitry asserts the first enable signal in response to the zero cross detection circuitry failing to assert the zero cross detection signal for a time interval equal to a first integer number of periods of an internal clock signal.

13. The control circuit of claim 12, wherein the logic circuitry is configured to disable the zero cross detection circuitry and the timing circuitry when the second enable signal is asserted and in response to a period of the PFM drive signal being lower than a period of the internal clock signal for a duration of time longer than a monitoring time interval.

14. The control circuit of claim 11, further comprising:
zero cross detection circuitry configured to assert a zero cross detection signal in response to detecting a zero value of the output current for the electronic converter device; and
timing circuitry configured to provide an internal clock signal with an internal clock period;
wherein the logic circuitry asserts the first enable signal in response to a period of the PFM drive signal being lower than a period of an internal clock signal.

15. The control circuit of claim 14, wherein the logic circuitry is configured to disable the zero cross detection circuitry and the timing circuitry when the second enable signal is asserted and in response to a period of the PFM drive signal being lower than a period of the internal clock signal for a duration of time longer than a monitoring time interval.

16. The control circuit of claim 11, comprising:
zero cross detection circuitry configured to assert a zero cross detection signal in response to detecting a zero value of the output current for the electronic converter device;
wherein the logic circuitry asserts the second enable signal in response to the zero cross detection signal.

17. The control circuit of claim 11, wherein the first control circuit comprises:
an error amplifier configured to provide a first error amplifier signal based on a difference between the feedback voltage and the first reference voltage level; and
a clamp circuit configured to limit a voltage level of the first error amplifier signal.

18. The control circuit of claim 11, wherein the logic circuitry is configured to calibrate the PFM signal generator circuit to set a duty cycle of the PFM drive signal equal to the duty cycle of the PWM drive signal in response to asserting the first enable signal.

19. The control circuit of claim 11, wherein the second control circuit comprises a comparator circuit configured to provide at an output node a comparison signal based on a comparison of the feedback voltage and the reference voltage level.

20. The control circuit of claim 19, wherein:
the comparator circuit of the second control circuit further comprises a reset node configured to reset the comparison signal; and
the logic circuitry is configured to provide to the comparator circuit an offset calibration signal as a function of the comparison signal in response to asserting the first enable signal.

21. The control circuit of claim 11, wherein the first reference voltage, the second reference voltage and the third reference voltage are equal to a same reference voltage.

22. An electronic device, comprising:
an electronic converter device with the electronic switch and an inductive circuit element coupled to the electronic switch; and
the control circuit according to claim 11.
